(19) United States
(12) Patent Application Publication
(10) Pub. No.: US 2026/0189201 A1
(43) Pub. Date: Jul. 2, 2026

(54) BIAS VOLTAGE GENERATORS

(71) Applicant: MEDIATEK INC, Hsinchu City (TW)

(72) Inventors: Yen-Chun Chan, Hsinchu City (TW); Sung-En Hsieh, Hsinchu City (TW); Yi-Hu Wang, Hsinchu City (TW)

(73) Assignee: MEDIATEK INC, Hsinchu City (TW)

(21) Appl. No.: 19/309,577

(22) Filed: Aug. 25, 2025

Related U.S. Application Data
(60) Provisional application No. 63/738,898, filed on Dec. 26, 2024.

(51) Int. Cl. H03F 3/20

(52) U.S. Cl. CPC H03F 3/20

(57) ABSTRACT

A bias voltage generator comprises a first bias voltage generating circuit and a second bias voltage generating circuit. Wherein the first bias voltage generating circuit comprises: a first bias circuit, comprising a first transistor and a first current source connected in cascode between a first supply voltage and a ground voltage; and a first amplifier circuit, configured for generating a first bias voltage according to an input common mode voltage and a first feedback voltage from the first transistor, and wherein the second bias voltage generating circuit comprises: a second bias circuit, comprising a second transistor and a second current source connected in cascode between a first supply voltage and a ground voltage; and a second amplifier circuit, configured for generating a second bias voltage according to the input common mode voltage and a second feedback voltage from the second transistor.

### CROSS REFERENCE TO RELATED APPLICATIONS

This application claims the benefit of U.S. Provisional Application No. 63/738,898, filed on Dec. 26, 2024. The content of the application is incorporated herein by reference.

### BACKGROUND

In modern Analog-to-Digital Converter (ADC) designs, the input buffer plays an important role in ensuring signal integrity and accurate conversion. Among various input buffer architectures, the class AB amplifier is widely recognized as a practical solution due to its ability to combine high linearity, low distortion, and moderate power consumption. As an input buffer, the class AB amplifier provides efficient impedance matching between the signal source and the ADC, thereby minimizing signal loss and preventing loading effects on the source. Moreover, the class AB configuration effectively reduces crossover distortion, ensuring precise amplification of input signals, which is particularly crucial for high-resolution ADCs. Its adaptability to varying load conditions and quick response to dynamic input signals makes it a reliable choice for applications requiring high-speed and high-accuracy conversion, such as in audio processing, industrial measurement systems, and communication devices.

The performance of a class AB amplifier as an input buffer is closely associated with its bias voltage circuit (e.g., bias voltage generator), which serves as an important design element. The bias voltage circuit plays a critical role in ensuring optimal amplifier operation by providing the appropriate bias conditions to minimize crossover distortion and improve efficiency. It stabilizes the operating conditions of the amplifier and helps achieve low distortion and high linearity across various scenarios. These characteristics are essential for maintaining consistent performance in demanding ADC applications.

As the bias voltage circuit is important to the overall performance of a class AB amplifier, its design and optimization remain topics worthy of in-depth exploration and refinement.

### SUMMARY

According to an embodiment of the disclosure, a bias voltage generator comprises a first bias voltage generating circuit, configured for generating a first bias voltage for a buffer circuit; and a second bias voltage generating circuit, configured for generating a second bias voltage for the buffer circuit, wherein the first bias voltage generating circuit comprises: a first bias circuit, comprising a first transistor and a first current source connected in cascode between a first supply voltage and a ground voltage; and a first amplifier circuit, configured for generating the first bias voltage according to an input common mode voltage and a first feedback voltage from the first transistor, wherein the drain-source voltage of the first transistor is the same as the drain-source voltage of a first power transistor of the buffer circuit, and wherein the second bias voltage generating circuit comprises: a second bias circuit, comprising a second transistor and a second current source connected in cascode between the first supply voltage and the ground voltage; and a second amplifier circuit, configured for generating the second bias voltage according to the input common mode voltage and a second feedback voltage from the second transistor, wherein the drain-source voltage of the second transistor is the same as the drain-source voltage of a second power transistor of the buffer circuit.

According to another embodiment of the disclosure, a bias voltage generator comprises a first bias voltage generating circuit, configured for generating a first bias voltage; and a second bias voltage generating circuit, configured for generating a second bias voltage, wherein the first bias voltage generating circuit comprises: a first bias circuit, comprising a first transistor and a first current source; and a first amplifier circuit, configured for generating the first bias voltage according to an input common mode voltage and a first feedback voltage from the first transistor, wherein the first transistor comprises a first terminal coupled to a first supply voltage, a second terminal coupled to a first terminal of the first current source, and a third terminal coupled to the output terminal of the first amplifier circuit and configured for outputting the first bias voltage, and wherein the second bias voltage generating circuit comprises: a second bias circuit, comprising a second transistor and a second current source; and a second amplifier circuit, configured for generating the second bias voltage according to the input common mode voltage and a second feedback voltage from the second bias circuit, wherein the second transistor comprises a first terminal coupled to a ground voltage, a second terminal coupled to a first terminal of the second current source, and a third terminal coupled to the output terminal of the second amplifier circuit and configured for outputting the second bias voltage, and wherein a second terminal of the first current source is coupled to the ground voltage and a second terminal of the second current source is coupled to the first supply voltage.

According to another embodiment of the disclosure, a bias voltage generator comprises a first bias voltage generating circuit, configured for generating a first bias voltage; and a second bias voltage generating circuit, configured for generating a second bias voltage, wherein the first bias voltage generating circuit comprises: a first bias circuit, comprising a first transistor and a first current source; a first amplifier circuit, configured for generating the first bias voltage according to an input common mode voltage and a first feedback voltage from the first transistor; and a first output isolation circuit, comprising a first circuit and a second circuit, wherein the first transistor comprises a first terminal coupled to a first supply voltage, a second terminal coupled to a first terminal of the first current source, and a third terminal coupled to the first output isolation circuit, and wherein the second bias voltage generating circuit comprises: a second bias circuit, comprising a second transistor and a second current source; a second amplifier circuit, configured for generating the second bias voltage according to the input common mode voltage and a second feedback voltage from the second bias circuit; and a second output isolation circuit, comprising a third circuit and a fourth circuit, wherein the second transistor comprises a first terminal coupled to a ground voltage, a second terminal coupled to a first terminal of the second current source, and a third terminal coupled to the second output isolation circuit, wherein a second terminal of the first current source is coupled to the ground voltage and a second terminal of the second current source is coupled to the first supply voltage, and wherein the second circuit is a replica of the first circuit and the fourth circuit is a replica of the third circuit.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exemplary block diagram of a circuitry for illustrating a proposed bias voltage generator according to an embodiment of the disclosure.

FIG. 2 shows an exemplary circuit diagram of the circuitry with the proposed bias voltage generator according to a first embodiment of the disclosure.

FIG. 3 is an exemplary block diagram of a circuitry for illustrating a proposed bias voltage generator according to another embodiment of the disclosure.

FIG. 4 shows an exemplary circuit diagram of the circuitry with the proposed bias voltage generator according to a second embodiment of the disclosure.

FIG. 5 shows an exemplary circuit diagram of the circuitry with the proposed bias voltage generator according to a third embodiment of the disclosure.

### DETAILED DESCRIPTION

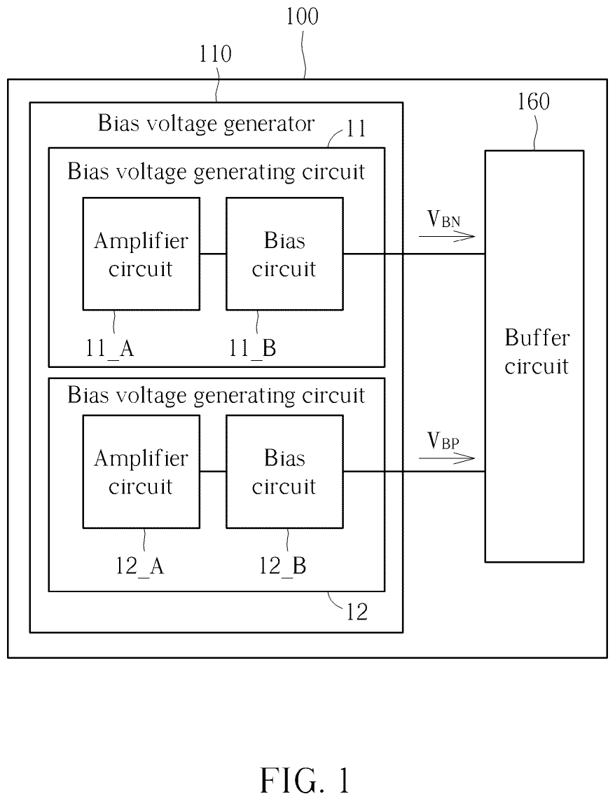

FIG. 1 is an exemplary block diagram of a circuitry for illustrating a proposed bias voltage generator according to an embodiment of the disclosure.

According to an embodiment of the disclosure, a circuitry 100 comprises a bias voltage generator 110 and a buffer circuit 160. The bias voltage generator 110 is configured to provide the buffer circuit 160 with at least two bias voltages, in FIG. 1 using two bias voltages, V_{BN} and V_{BP,} for illustration purposes. In some embodiments of the disclosure, an input buffer or an amplifier is implemented by using the circuitry 100, which comprises a bias voltage generator and a buffer circuit. In other embodiments an input buffer or an amplifier may also be implemented by using a circuitry comprising only a buffer circuit, such as the buffer circuit 160, with the bias voltages, such as V_{BN} and V_{BP}, being provided by an external bias voltage generator such as the proposed bias voltage generator, and thus this disclosure is not limited to any specific implementation.

More specific, in some embodiments of the disclosure, the buffer circuit 160 may be implemented as a class AB amplifier or a class AB buffer, and the bias voltages V_{BN} and V_{BP} are provided by the proposed bias voltage generator, such as the bias voltage generator 110. Note that when a class AB amplifier is used as the input buffer in an ADC, the class AB amplifier essentially functions as a class AB buffer. Therefore, in this disclosure, the class AB amplifier serves as an implementation of a class AB buffer, combining its inherent advantages to optimize signal transmission and improve ADC performance.

According to an embodiment of the disclosure, the bias voltage generator 110 comprises a bias voltage generating circuit 11 (e.g., a first bias voltage generating circuit) configured to generate the bias voltage V_{BN} (e.g., a first bias voltage) and a bias voltage generating circuit 12 (e.g., a second bias voltage generating circuit) configured to generate the bias voltage V_{BP} (e.g., a second bias voltage). It should be noted that, although there are only two bias voltage generating circuits and two bias voltages shown in FIG. 1. The numbers of bias voltage generating circuits inside the bias voltage generator 110 and the numbers of bias voltages generated by the bias voltage generator 100 may be more than two, which depends on the requirement of the circuit design, for example, depends on the numbers of power transistors in the Class AB amplifier.

The bias voltage generating circuit 11 comprises an amplifier circuit 11_A (e.g., a first amplifier circuit) and a bias circuit 11_B (e.g., a first bias circuit). The amplifier circuit 11_A receives a first feedback voltage from the bias circuit 11_B and is configured to control a common mode voltage of the buffer circuit 160.

The bias voltage generating circuit 12 comprises an amplifier circuit 12_A (e.g., a second amplifier circuit) and a bias circuit 12_B (e.g., a second bias circuit). The amplifier circuit 12_A receives a second feedback voltage from the bias circuit 12_B and is configured to control the common mode voltage of the buffer circuit 160.

According to an embodiment of the disclosure, the voltages V_{BN} and V_{BP} are output by the bias voltage generator 110 for biasing the buffer circuit 160. In the embodiments of the disclosure, with the circuit design of the proposed bias voltage generator, a drain-source voltage V_{DS} of a transistor in the bias circuit 11_B is the same as a drain-source voltage V_{DS} of a first power transistor in the buffer circuit 160 and a drain-source voltage V_{DS} of a transistor in the bias circuit 12_B is the same as a drain-source voltage V_{DS} of a second power transistor in the buffer circuit 160. In this manner, a result of matching V_{DS} is achieved by the proposed bias voltage generator. Matching V_{DS} is a circuit matching technique aimed at ensuring the circuit operates stably and efficiently under different process corner variations by controlling and matching the drain-source voltage (V_{DS}) of transistors.

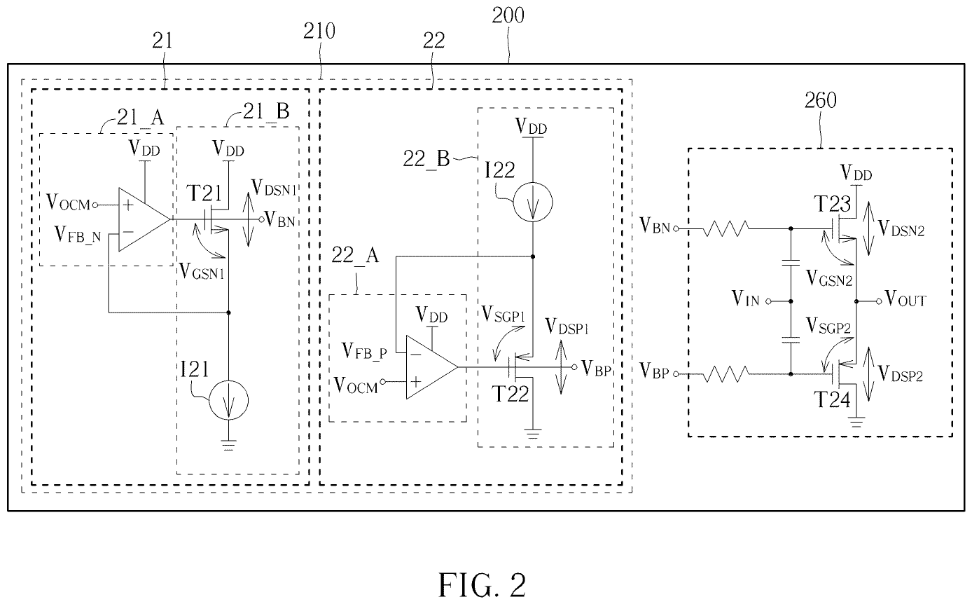

FIG. 2 shows an exemplary circuit diagram of the circuitry with the proposed bias voltage generator according to a first embodiment of the disclosure. The circuitry 200 may be an implementation of the circuitry 100, and may comprise a bias voltage generator 210 and a buffer circuit 260. The bias voltage generator 210 is configured to provide the voltages V_{BN} and V_{BP} for biasing the buffer circuit 260.

According to an embodiment of the disclosure, the bias voltage generator 210 comprises a bias voltage generating circuit 21 configured to generate the bias voltage V_{BN} and a bias voltage generating circuit 22 configured to generate the bias voltage V_{BP}.

The bias voltage generating circuit 21 comprises an amplifier circuit 21_A (e.g., a first amplifier circuit) and a bias circuit 21_B (e.g., a first bias circuit). The amplifier circuit 21_A receives a first feedback voltage V_{FB_N} from the bias circuit 21_B and is configured to control a common mode voltage of the buffer circuit 260.

The bias voltage generating circuit 22 comprises an amplifier circuit 22_A (e.g., a second amplifier circuit) and a bias circuit 22_B (e.g., a second bias circuit). The amplifier circuit 22_A receives a second feedback voltage V_{FB_P} from the bias circuit 22_B and is configured to control the common mode voltage of the buffer circuit 260.

According to an embodiment of the disclosure, the bias circuit 21_B comprises a transistor T21 and a current source I21. The transistor T21 comprises a first terminal coupled to a first supply voltage, such as the V_{DD} (e.g., 0.85 volt), a second terminal coupled to a first terminal of the current source I21, and a third terminal configured to output the bias voltage V_{BN}.

According to an embodiment of the disclosure, the amplifier circuit 21_A comprises a first input terminal receiving a common mode voltage V_{OCM}, a second input terminal coupled to a common node between the transistor T21 and the current source I21 and receiving the first feedback voltage V_{FB_N}, a supply voltage input terminal coupled to a second supply voltage and an output terminal coupled to the third terminal of the transistor T21.

According to an embodiment of the disclosure, the bias circuit 22_B comprises a transistor T22 and a current source I22. The transistor T22 comprises a first terminal coupled to a ground voltage, a second terminal coupled to a first terminal of the current source I22, and a third terminal configured to output the bias voltage V_{BP}.

According to an embodiment of the disclosure, the amplifier circuit 22_A comprises a first input terminal receiving the common mode voltage V_{OCM}, a second input terminal coupled to a common node between the transistor T22 and the current source I22 and receiving the second feedback voltage V_{FB_P}, a supply voltage input terminal coupled to the second supply voltage and an output terminal coupled to the third terminal of the transistor T22.

According to an embodiment of the disclosure, a second terminal of the current source I21 is coupled to the ground voltage and a second terminal of the current source I22 is coupled to the first supply voltage.

According to an embodiment of the disclosure, the first supply voltage and the second supply voltage are the same. For example, the amplifier circuits 21_A and 22_A and the bias circuits 21_B and 22_B are supplied by the same supply voltage, such as the V_{DD} shown in FIG. 2.

In the embodiments of the disclosure, the transistor T21 is an N-type Metal-Oxide-Semiconductor (MOS) (NMOS) transistor and the transistor T22 is a P-type MOS (PMOS) transistor. In addition, the buffer circuit 260 may consist of a push-pull source follower (PPSF) which comprises power transistors T23 and T24, where the power transistor T23 is an NMOS transistor and the power transistor T24 is a PMOS transistor.

According to an embodiment of the disclosure, the first terminal of the transistor T21 is the drain electrode of the transistor T21, the second terminal of the transistor T21 is the source electrode of the transistor T21, and the third terminal of the transistor T21 is the gate electrode of the transistor T21. Similarly, the first terminal of the transistor T22 is the drain electrode of the transistor T22, the second terminal of the transistor T22 is the source electrode of the transistor T22, and the third terminal of the transistor T22 is the gate electrode of the transistor T22.

According to an embodiment of the disclosure, a size of the power transistor T23 is a multiple of a size of the transistor T21, and a size of the power transistor T24 is a multiple of a size of the transistor T22. For example, the size of the power transistor T23 may be N times of the size of the transistor T21, and the size of the power transistor T24 may be N times of the size of the transistor T22, where N is a positive number.

In addition, according to an embodiment of the disclosure, the transistors T21, T22, and the power transistors T23 and T24 may respectively consist of a single or multiple transistors.

It should be noted, the structure of the buffer circuit 260 is just for illustration purpose, in other embodiments, there may be more than two power transistors in the buffer circuit 260. In summary, the numbers of the bias voltage generating circuits (each may generate a bias voltage) inside the bias voltage generator 210 should be the same as the numbers of the numbers of power transistors in the buffer circuit 260. For example, if there is a third power transistor (e.g., a NMOS power transistor) in the buffer circuit 260, a third bias voltage generating circuit which may be the same as the bias voltage generating circuit 21 may be set in the bias voltage generator 210 for generating a third bias voltage for the third power transistor. For another example, if there is a fourth power transistor (e.g., a PMOS power transistor) in the buffer circuit 260, a fourth bias voltage generating circuit which may be the same as the bias voltage generating circuit 22 may be set in the bias voltage generator 210 for generating a fourth bias voltage for the fourth power transistor.

As mentioned above, the proposed bias voltage generator, such as the bias voltage generator 110 and/or 210, is separated into independent loops for generating the bias voltages respectively. For example, in FIG. 1, the bias voltage generating circuits 11 and 12 are two independent loops for generating the bias voltages V_{BN} and V_{BP} respectively. Similarly, as depicted in FIG. 2, the bias voltage generating circuits 21 and 22 are two independent loops for generating the bias voltages V_{BN} and V_{BP} respectively. Since the bias voltage generator in this disclosure is separated into independent loops (e.g., loops 11,12 or loops 21,22) for generating the bias voltages (e.g., V_{BN} and V_{BP}) respectively, the stacking transistors in each loop is reduced, which relaxes the voltage headroom and is friendly to low-voltage design. Besides, since the bias voltage generator is separated into independent loops (e.g., loops 11,12 or loops 21,22) for generating the bias voltages (e.g., V_{BN} and V_{BP}) respectively, each loop can set a transistor to replicate the drain-source voltage V_{DS} of a power transistor in buffer circuit. In this manner, a result of matching V_{DS} is achieved by the proposed bias voltage generator. As a result, the bias voltages (e.g., V_{BN} and V_{BP}) generated by the bias voltage generator can make the output voltage V_{OUT} of the buffer circuit 260 be well controlled by the common mode voltage V_{OCM}.

More specific, as shown in FIG. 2, the drain-source voltage V_{DSN1} of the transistor T21 is the same as the drain-source voltage V_{DSN2} of the power transistor T23 in the buffer circuit 260, and a drain-source voltage V_{DSP1} of the transistor T22 is the same as the drain-source voltage V_{DSP2} of the power transistor T24 in the buffer circuit 260. That is, in the embodiments of the disclosure, V_{DSN1}=V_{DSN2} and V_{DSP1}=V_{2DSP}. In this manner, a result of matching V_{DS} is achieved by the proposed bias voltage generator. As a result, the bias voltages VBN and VBP generated by the bias voltage generator 110 and/or 210 can make the output voltage VOUT of the buffer circuit 260 be well controlled by the common mode voltage VOCM. For example, when V_{DSN1}=V_{DSN2} and V_{DSP1}=V_{DSP2}, the output voltage VOUT of the buffer circuit 260 is the same as the common mode voltage VOCM received by the amplifier circuits 21_A and 22_A at the direct current (DC) bias point. Wherein at the DC bias point, there is no alternating current (AC) input (for example, the AC term of the input voltage VIN is zero) in the buffer circuit. Furthermore, in this disclosure, in FIG. 2, at the DC bias point, the gate-source voltage

V_{GSN1} of the transistor T21 is the same as the gate-source voltage V_{GSN2} of the power transistor T23, and the source-gate voltage V_{SGP1} of the transistor T22 is the same as the source-gate voltage V_{SGP2} of the power transistor T24.

Comparing to the conventional bias circuit design which utilizes diode-connected transistor, in the proposed bias circuits, no diode-connected transistor is utilized. The diode-connected transistor in the conventional bias circuit design causes different drain-source voltages between the diode-connected transistor and the transistor in the buffer circuit, leading to large common mode voltage variation at buffer output caused by channel length modulation. As mentioned above, the proposed bias circuits can solve the problems cause by the use of diode-connected transistor.

In addition, in the proposed bias circuits, the number of transistor(s) comprised in each bias circuit (for example, the number is 1 as shown in FIG. 2 when the transistor(s) comprised in the current source is not counted) is fewer than conventional bias circuit design. As the number of stacked transistors in each loop of the bias voltage generator is reduced, the need of a high voltage supply voltage for driving a greater number of transistors as in the conventional bias circuit design is avoided, which relaxes the voltage headroom and makes the proposed bias circuits to be friendly to low-voltage design. For example, in FIG. 2, the supply voltage provided for the amplifier circuits 21_A and 22_A is 0.85 v, which is the same as the supply voltage provided for the bias circuits 21_B and 22_B.

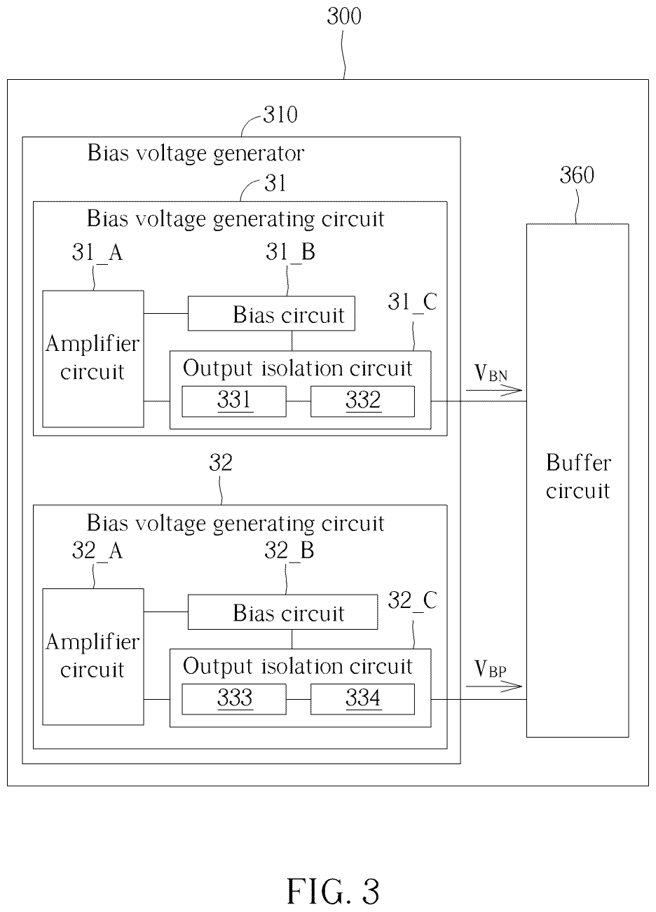

FIG. 3 is an exemplary block diagram of a circuitry for illustrating a proposed bias voltage generator according to another embodiment of the disclosure.

According to an embodiment of the disclosure, circuitry 300 comprises a bias voltage generator 310 and a buffer circuit 360. The bias voltage generator 310 is configured to provide the buffer circuit 360 with at least two bias voltages, in FIG. 3 using two bias voltages V_{BN} and V_{BP} for illustration purpose. In some embodiments of the disclosure, implementing an input buffer or an amplifier by using the circuitry 300 comprising a bias voltage generator and a buffer circuit. In other embodiments an input buffer or an amplifier may also be implemented by using a circuitry comprising only a buffer circuit, such as the buffer circuit 360, with the bias voltages, such as V_{BN} and V_{BP}, being provided by an external bias voltage generator such as the proposed bias voltage generator, and thus the disclosure is not limited to any specific implementation.

More specific, in some embodiments of the disclosure, the buffer circuit 360 may be implemented as a class AB amplifier or a class AB buffer, and the bias voltages V_{BN} and V_{BP} are provided by the proposed bias voltage generator, such as the bias voltage generator 310. Note that when a class AB amplifier is used as the input buffer in an ADC, the class AB amplifier essentially functions as a class AB buffer. Therefore, in this disclosure, the class AB amplifier serves as an implementation of a class AB buffer, combining its inherent advantages to optimize signal transmission and improve ADC performance.

According to an embodiment of the disclosure, the bias voltage generator 310 comprises a bias voltage generating circuit 31 (e.g., a first bias voltage generating circuit) configured to generate the bias voltage V_{BN} (e.g., a first bias voltage) and a bias voltage generating circuit 32 (e.g., a second bias voltage generating circuit) configured to generate the bias voltage V_{BP} (e.g., a second bias voltage). It should be noted that, although there are only two bias voltage generating circuits and two bias voltages shown in FIG. 3. The numbers of bias voltage generating circuits inside the bias voltage generator 310 and the numbers of bias voltages generated by the bias voltage generator 300 may be more than two, which depends on the requirement of the circuit design, for example, depends on the numbers of power transistors in the Class AB amplifier.

The bias voltage generating circuit 31 comprises an amplifier circuit 31_A (e.g., a first amplifier circuit), a bias circuit 31_B (e.g., a first bias circuit) and an output isolation circuit 31_C (e.g., a first output isolation circuit). The amplifier circuit 31_A receives a first feedback voltage from the bias circuit 31_B and is configured to control a common mode voltage of the buffer circuit 360.

The bias voltage generating circuit 32 comprises an amplifier circuit 32_A (e.g., a second amplifier circuit), a bias circuit 32_B (e.g., a second bias circuit) and an output isolation circuit 32_C (e.g., a second output isolation circuit). The amplifier circuit 32_A receives a second feedback voltage from the bias circuit 32_B and is configured to control the common mode voltage of the buffer circuit 360.

According to an embodiment of the disclosure, the output isolation circuit 31_C comprises at least a circuit 331 (e.g., a first circuit) and a circuit 332 (e.g., a second circuit), and the output isolation circuit 32_C comprises at least a circuit 333 (e.g., a third circuit) and a circuit 334 (e.g., a fourth circuit). In some embodiments of the disclosure, the circuit 332 is a replica of the circuit 331 and the circuit 334 is a replica of the circuit 333. In other embodiments, the number of transistors in circuit 332 may be Z times of the number of transistors in the circuit 331, and the number of transistors in circuit 334 may be M times the number of transistors in the circuit 333, wherein Z and M are positive numbers. In another embodiment, if there is a third bias voltage generating circuit, this third bias voltage generating circuit may also comprise an output isolation circuit which has the same structure of the output isolation circuit 31_C or the output isolation circuit 32_C.

According to an embodiment of the disclosure, the voltages V_{BN} and V_{BP} are output by the bias voltage generator 310 for biasing the buffer circuit 360. In the embodiments of the disclosure, with the circuit design of the proposed bias voltage generator, a drain-source voltage V_{DS} of a transistor in the bias circuit 31_B is the same as a drain-source voltage V_{DS} of a first power transistor in the buffer circuit 360 and a drain-source voltage V_{DS} of a transistor in the bias circuit 32_B is the same as a drain-source voltage V_{DS} of a second power transistor in the buffer circuit 360. In this manner, a result of matching V_{DS} is achieved by the proposed bias voltage generator.

In addition, in the embodiments of the disclosure, the stability, driving capability, and isolation of the overall circuit is improved by introducing the replica stages.

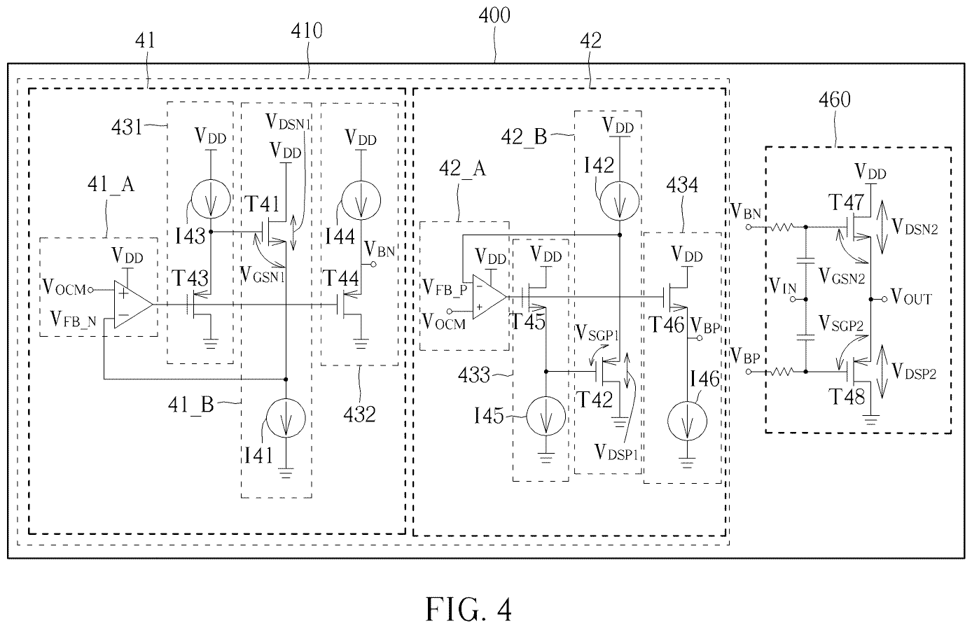

FIG. 4 shows an exemplary circuit diagram of the circuitry with the proposed bias voltage generator according to a second embodiment of the disclosure. The circuitry 400 may be an implementation of the circuitry 300, and may comprise a bias voltage generator 410 and a buffer circuit 460. The bias voltage generator 410 is configured to provide the voltages V_{BN} and V_{BP} for biasing the buffer circuit 460.

According to an embodiment of the disclosure, the bias voltage generator 410 comprises a bias voltage generating circuit 41 configured to generate the bias voltage V_{BN} and a bias voltage generating circuit 42 configured to generate the bias voltage V_{BP}.

The bias voltage generating circuit 41 comprises an amplifier circuit 41_A (e.g., a first amplifier circuit), a bias circuit 41_B (e.g., a first bias circuit) and an output isolation circuit (e.g., a first output isolation circuit). The amplifier circuit 41_A receives a first feedback voltage V_{FB_N} from the bias circuit 41_B and is configured to control a common mode voltage of the buffer circuit 460.

The bias voltage generating circuit 42 comprises an amplifier circuit 42_A (e.g., a second amplifier circuit), a bias circuit 42_B (e.g., a second bias circuit) and an output isolation circuit (e.g., a second output isolation circuit). The amplifier circuit 42_A receives a second feedback voltage V_{FB_P} from the bias circuit 42_B and is configured to control the common mode voltage of the buffer circuit 460.

According to an embodiment of the disclosure, the bias circuit 41_B comprises a transistor T41 and a current source I41. The transistor T41 comprises a first terminal coupled to a first supply voltage, such as the V_{DD}, a second terminal coupled to a first terminal of the current source I41, and a third terminal.

According to an embodiment of the disclosure, the amplifier circuit 41_A comprises a first input terminal receiving a common mode voltage V_{OCM}, a second input terminal coupled to a common node between the transistor T41 and the current source I41 and receiving the first feedback voltage V_{FB_N}, a supply voltage input terminal coupled to a second supply voltage and an output terminal.

According to an embodiment of the disclosure, the bias circuit 42_B comprises a transistor T42 and a current source I42. The transistor T42 comprises a first terminal coupled to a ground voltage, a second terminal coupled to a first terminal of the current source I42, and a third terminal.

According to an embodiment of the disclosure, the amplifier circuit 42_A comprises a first input terminal receiving the common mode voltage V_{OCM}, a second input terminal coupled to a common node between the transistor T42 and the current source I42 and receiving the second feedback voltage V_{FB_P}, a supply voltage input terminal coupled to the second supply voltage and an output terminal.

According to an embodiment of the disclosure, a second terminal of the current source I41 is coupled to the ground voltage and a second terminal of the current source I42 is coupled to the first supply voltage.

According to an embodiment of the disclosure, the first output isolation circuit comprises a circuit 431 (e.g., a first circuit) and a circuit 432 (e.g., a second circuit), and the second output isolation circuit comprises a circuit 433 (e.g., a third circuit) and a circuit 434 (e.g., a fourth circuit). In this embodiment, the circuit 432 is a replica of the circuit 431 and the circuit 434 is a replica of the circuit 433. In other embodiments, the number of transistors in circuit 432 may be Z times of the number of transistors in the circuit 431, and the number of transistors in circuit 434 may be M times of the number of transistors in the circuit 433, wherein Z and M are positive number.

More specific, according to an embodiment of the disclosure, the circuit 431 comprises a transistor T43 and a current source I43. The transistor T43 comprises a first terminal coupled to the ground voltage, a second terminal coupled to a first terminal of the current source I43 and a third terminal coupled to the output terminal of the amplifier circuit 41_A. A second terminal of the current source I43 is coupled to the first supply voltage, and a common node between the transistor T43 and the current source I43 is coupled to the third terminal of the transistor T41.

According to an embodiment of the disclosure, the circuit 432, which is a replica of the circuit 431 (e.g., comprising the same components and having the same circuit structure as the circuit 431) comprises a transistor T44 and a current source I44. The transistor T44 comprises a first terminal coupled to the ground voltage, a second terminal coupled to a first terminal of the current source I44 and a third terminal coupled to the output terminal of the amplifier circuit 41_A. A second terminal of the current source I44 is coupled to the first supply voltage, and a common node between the transistor T44 and the current source I44 is configured to output the bias voltage V_{BN}.

In addition, according to an embodiment of the disclosure, the circuit 433 comprises a transistor T45 and a current source I45. The transistor T45 comprises a first terminal coupled to the first supply voltage, a second terminal coupled to a first terminal of the current source I45 and a third terminal coupled to the output terminal of the amplifier circuit 42_A. A second terminal of the current source I45 is coupled to the ground voltage, and a common node between the transistor T45 and the current source I45 is coupled to the third terminal of the transistor T42.

According to an embodiment of the disclosure, the circuit 434, which is a replica of the circuit 433 (e.g., comprising the same components and having the same circuit structure as the circuit 433) comprises a transistor T46 and a current source I46. The transistor T46 comprises a first terminal coupled to the first supply voltage, a second terminal coupled to a first terminal of the current source I46 and a third terminal coupled to the output terminal of the amplifier circuit 42_A. A second terminal of the current source I46 is coupled to the ground voltage, and a common node between the transistor T46 and the current source I46 is configured to output the bias voltage V_{BP}.

According to an embodiment of the disclosure, the first supply voltage and the second supply voltage are the same. For example, the amplifier circuits 41_A and 42_A, the bias circuits 41_B and 42_B and the circuits 431, 432, 433 and 434 are supplied by the same supply voltage, such as the V_{DD} shown in FIG. 4. In an alternative embodiment, the first supply voltage and the second supply voltage may also be different.

In the embodiments of the disclosure, the transistors T41, T45 and T46 are NMOS transistors and the transistors T42, T43 and T44 are PMOS transistors. In addition, the buffer circuit 460 may consist of a PPSF which comprises transistors T47 and T48, wherein the transistor T47 is an NMOS transistor and the transistor T48 is a PMOS transistor.

According to an embodiment of the disclosure, the first terminal of the transistors T41-T48 is the drain electrode thereof, the second terminal of the transistors T41-T48 is the source electrode thereof, and the third terminal of the transistors T41-T48 is the gate electrode thereof.

According to an embodiment of the disclosure, a size of the power transistor T47 is a multiple of a size of the transistor T41, and a size of the power transistor T48 is a multiple of a size of the transistor T42. For example, the size of the power transistor T47 may be N times of the size of the transistor T41, and the size of the power transistor T48 may be N times of the size of the transistor T42, where N is a positive number.

In addition, according to an embodiment of the disclosure, the transistors T41-T48may respectively consist of a single or multiple transistors.

According to an embodiment of the disclosure, the proposed bias voltage generator, such as the bias voltage generator 310 and/or 410, is separated into two loops for generating the bias voltages respectively. For example, in FIG. 3, the bias voltage generating circuits 31 and 32 are two independent loops for generating the bias voltages V_{BN} and V_{BP} respectively. Similarly, as depicted in FIG. 4, the bias voltage generating circuits 41 and 42 are two independent loops for generating the bias voltages V_{BN} and V_{BP} respectively.

In the embodiments of the disclosure, in the two separated loops, the drain-source voltage V_{DS} of the transistors in bias voltage generator and the drain-source voltage V_{DS} of the power transistors in buffer circuit the same. In this manner, a result of matching V_{DS} is achieved by the proposed bias voltage generator. In addition, the separated loops reduce the stacking transistors in each branch of the bias voltage generator, which relaxes the voltage headroom and is friendly to low-voltage design.

More specific, as shown in FIG. 4, the drain-source voltage V_{DSN1} of the transistor T41 is the same as the drain-source voltage V_{DSN2} of the power transistor T47 in the buffer circuit 460, and a drain-source voltage V_{DSP1} of the transistor T42 is the same as the drain-source voltage V_{DSP2} of the power transistor T48 in the buffer circuit 460. That is, V_{DSN1}=V_{DSN2} and V_{DSP1}=V_{DSP2}. In this manner, a result of matching V_{DS} is achieved by the proposed bias voltage generator. In addition, the output voltage V_{OUT} of the buffer circuit 460 is well controlled by the

common mode voltage V_{OCM} received by the amplifier circuits 41_A and 42_A. For the DC bias point, the output voltage V_{OUT} of the buffer circuit 460 is the same as the common mode voltage V_{OCM} received by the amplifier circuits 41_A and 42_A. Furthermore, at the DC bias point, the gate-source voltage V_{GSN1} of the transistor T41 is the same as the gate-source voltage V_{GSN2} of the power transistor T47, and the source-gate voltage V_{SGP1} of the transistor T42 is the same as the source-gate voltage V_{SGP2} of the power transistor T48.

In addition, in the embodiments of the disclosure, replica stages in the output isolation circuits are added to isolate nodes for providing the bias voltages V_{BN} and V_{BP} and internal nodes for generating the feedback voltage V_{FB_N} and t V_{FB_P}). Therefore, the feedback voltages V_{FB_N} and t V_{FB_P} are not affected by the operation of the buffer circuit 460. This enhancement improves the stability, driving capability, and isolation of the overall circuit.

Comparing to the conventional bias circuit design which utilizes diode-connected transistor, in the proposed bias circuits, no diode-connected transistor is utilized. The diode-connected transistor in the conventional bias circuit design causes different drain-source voltages between the diode-connected transistor and the transistor in the buffer circuit, leading to large common mode voltage variation at buffer output caused by channel length modulation. As mentioned above, the proposed bias circuits can solve the problems cause by the use of diode-connected transistor.

In addition, in the proposed bias circuits, the number of transistor(s) comprised in each bias circuit (for example, the number is 1 as shown in FIG. 4 when the transistor(s) comprised in the current source is not counted) is fewer than conventional bias circuit design. As the number of stacked transistors in each loop of the bias voltage generator is reduced, the need of a high voltage supply voltage for driving a greater number of transistors as in the conventional bias circuit design is avoided, which relaxes the voltage headroom and makes proposed bias circuits to be friendly to low-voltage design. For example, in FIG. 4, the supply voltage provided for the amplifier circuits 41_A and 42_A is 0.85 v, which is the same as the supply voltage provided for the bias circuits 41_B and 42_B.

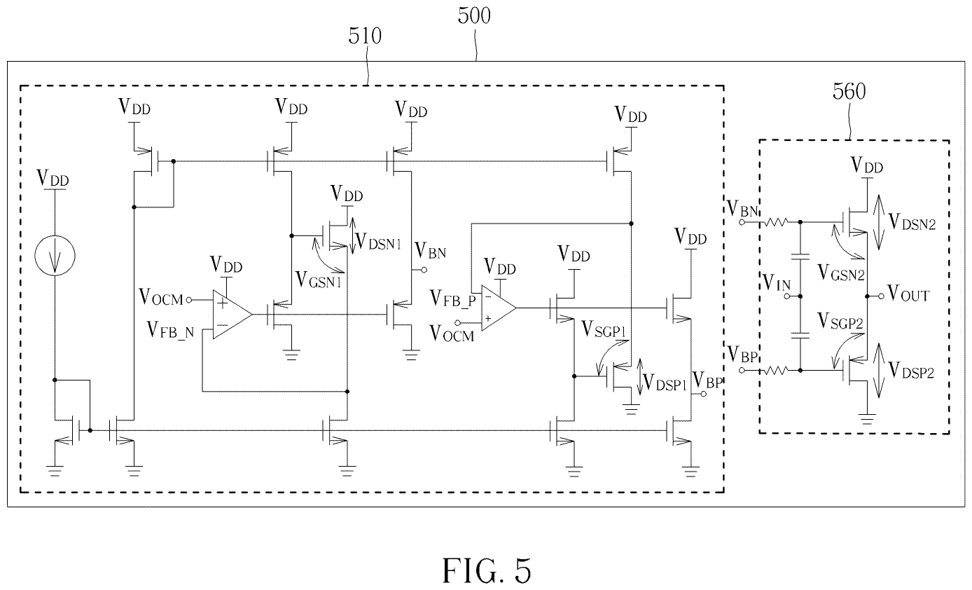

FIG. 5 shows an exemplary circuit diagram of the circuitry with the proposed bias voltage generator according to a third embodiment of the disclosure. The circuitry 500 may be an implementation of the circuitry 400, and may comprise a bias voltage generator 510 and a buffer circuit 560. The bias voltage generator 510 is configured to provide the voltages V_{BN} and V_{BP} for biasing the buffer circuit 560.

In the circuitry 500, some current sources in the bias voltage generator 510 are implemented by PMOS transistors, and some current sources that act as the current sinks in the bias voltage generator 510 are implemented by NMOS transistors, providing a more practical implementation. Note that FIG. 5 merely shows a possible implementation of using PMOS and NMOS transistors for current sources and sinks, and the disclosure should not be limited thereto. Other implementations, such as using cascode current sources, may also be employed in the proposed bias voltage generator to enhance output impedance and reduce corner variation in bias voltage.

In summary, the proposed bias voltage generator is suitable for a buffer circuit or an amplifier circuit, especially suitable for a class AB buffer or a class AB amplifier. In addition, the proposed bias voltage generator is separated into multiple loops, which avoids the use of diode-connected transistors and avoids the need for a high voltage supply voltage, such as a high-voltage V_{DD}. In addition, the proposed bias voltage generator reduces the number of stacking transistors in each branch of the bias voltage generator, which relaxes the voltage headroom and is friendly to low-voltage design.

In addition, as no diode-connected transistor is utilized in the proposed bias voltage generator, a result of matching V_{DS} is achieved. Matching drain-source voltages between bias voltage generator and buffer circuit or amplifier circuit leads to a smaller output common mode voltage variation. Therefore, the proposed bias circuits solve the problem of large common mode voltage variation at buffer output caused by channel length modulation, which is due to unmatched drain-source voltage.

In addition, in some embodiments of the disclosure, replica stages in the output isolation circuits are added to isolate nodes for providing the bias voltages and internal node for generating the feedback voltage. That is, in some embodiments of the disclosure, the bias voltages V_{BN} and V_{BP} are provided by the replica circuits instead of being directly provided by the bias circuits. Therefore, the nodes for providing the bias voltages V_{BN} and V_{BP} is isolated from the internal node for generating the feedback voltage, therefore the feedback voltages are not affected by the operation of the buffer circuit. This enhancement improves the stability, driving capability, and isolation of the overall circuit.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A bias voltage generator, comprising:
a first bias voltage generating circuit, configured for generating a first bias voltage for a buffer circuit; and
a second bias voltage generating circuit, configured for generating a second bias voltage for the buffer circuit,
wherein the first bias voltage generating circuit comprises:
a first bias circuit, comprising a first transistor and a first current source connected in cascode between a first supply voltage and a ground voltage; and
a first amplifier circuit, configured for generating the first bias voltage according to an input common mode voltage and a first feedback voltage from the first transistor,
wherein the drain-source voltage of the first transistor is the same as the drain-source voltage of a first power transistor of the buffer circuit, and
wherein the second bias voltage generating circuit comprises:
a second bias circuit, comprising a second transistor and a second current source connected in cascode between the first supply voltage and the ground voltage; and
a second amplifier circuit, configured for generating the second bias voltage according to the input common mode voltage and a second feedback voltage from the second transistor,
wherein the drain-source voltage of the second transistor is the same as the drain-source voltage of a second power transistor of the buffer circuit.

2. The bias voltage generator of claim 1, wherein the first amplifier circuit comprises:
a first input terminal, configured for receiving the input common mode voltage;
a second input terminal, coupled to a common node between the first transistor and the first current source and configured for receiving the first feedback voltage;
a supply voltage input terminal, coupled to a second supply voltage; and
an output terminal for generating the first bias voltage, and
wherein the second amplifier circuit comprises:
a first input terminal, configured for receiving the input common mode voltage;
a second input terminal, coupled to a common node between the second transistor and the second current source and configured for receiving the second feedback voltage;
a supply voltage input terminal, coupled to the second supply voltage; and
an output terminal for generating the second bias voltage.

3. The bias voltage generator of claim 2, wherein the first supply voltage and the second supply voltage are the same.

4. The bias voltage generator of claim 2, wherein the first transistor comprises:
a drain terminal, coupled to the first supply voltage;
a source terminal, coupled to a first terminal of the first current source; and
a gate terminal, coupled to the output terminal of the first amplifier circuit;
wherein the second terminal of the first current source is coupled to the ground voltage;
wherein the second transistor comprises:
a drain terminal, coupled to the ground voltage;
a source terminal, coupled to a first terminal of the second current source; and
a gate terminal, coupled to the output terminal of the second amplifier circuit;
wherein the second terminal of the second current source is coupled to the first supply voltage.

5. The bias voltage generator of claim 4, wherein the first bias voltage is output from the gate terminal of the first transistor and the second bias voltage is output from the gate terminal of the second transistor.

6. The bias voltage generator of claim 1, wherein the first transistor is an N-type Metal-Oxide-Semiconductor (MOS) (NMOS) transistor and the second transistor is a P-type MOS (PMOS) transistor.

7. The bias voltage generator of claim 2, wherein the first bias voltage generating circuit further comprises a first output isolation circuit, the first output isolation circuit comprises at least a first circuit and a second circuit, and the second bias voltage generating circuit further comprises a second output isolation circuit, the second output isolation circuit comprises at least a third circuit and a fourth circuit, and wherein the second circuit is a replica of the first circuit and the fourth circuit is a replica of the third circuit.

8. The bias voltage generator of claim 2, wherein the first bias voltage generating circuit further comprises a first output isolation circuit, the first output isolation circuit comprises at least a first circuit and a second circuit, and the second bias voltage generating circuit further comprises a second output isolation circuit, the second output isolation circuit comprises at least a third circuit and a fourth circuit, and wherein the number of transistors in the second circuit is a multiple of the number of transistors in the first circuit, the number of transistors in the fourth circuit is a multiple of the number of transistors in the third circuit.

9. The bias voltage generator of claim 7, wherein the first circuit comprises:
a third transistor and a third current source,
wherein the third transistor comprises a first terminal coupled to the ground voltage, a second terminal coupled to a first terminal of the third current source and a third terminal coupled to the output terminal of the first amplifier circuit, a second terminal of the third current source is coupled to the first supply voltage, and a common node between the third transistor and the third current source is coupled to the third terminal of the first transistor, and
wherein the second circuit comprises:
a fourth transistor and a fourth current source,
wherein the fourth transistor comprises a first terminal coupled to the ground voltage, a second terminal coupled to a first terminal of the fourth current source and a third terminal coupled to the output terminal of the first amplifier circuit, a second terminal of the fourth current source is coupled to the first supply voltage, and a common node between the fourth transistor and the fourth current source is configured for outputting the first bias voltage.

10. The bias voltage generator of claim 9,
wherein the first terminal of the third transistor is the drain terminal of the third transistor, the second terminal of the third transistor is the source terminal of the third transistor, and the third terminal of the third transistor is the gate terminal of the third transistor;
wherein the first terminal of the fourth transistor is the drain terminal of the fourth transistor, the second terminal of the fourth transistor is the source terminal of the fourth transistor, and the third terminal of the fourth transistor is the gate terminal of the fourth transistor.

11. The bias voltage generator of claim 7, wherein the third circuit comprises:
a fifth transistor and a fifth current source,
wherein the fifth transistor comprises a first terminal coupled to the first supply voltage, a second terminal coupled to a first terminal of the fifth current source and a third terminal coupled to the output terminal of the second amplifier circuit, a second terminal of the fifth current source is coupled to the ground voltage, and a common node between the fifth transistor and the fifth current source is coupled to the third terminal of the second transistor, and
wherein the fourth circuit comprises:
a sixth transistor and a sixth current source,
wherein the sixth transistor comprises a first terminal coupled to the first supply voltage, a second terminal coupled to a first terminal of the sixth current source and a third terminal coupled to the output terminal of the second amplifier circuit, a second terminal of the sixth current source is coupled to the ground voltage, and a common node between the sixth transistor and the sixth current source is configured for outputting the second bias voltage.

12. The bias voltage generator of claim 11,
wherein the first terminal of the fifth transistor is the drain terminal of the fifth transistor, the second terminal of the fifth transistor is the source terminal of the fifth transistor, and the third terminal of the fifth transistor is the gate terminal of the fifth transistor;
wherein the first terminal of the sixth transistor is the drain terminal of the sixth transistor, the second terminal of the sixth transistor is the source terminal of the sixth transistor, and the third terminal of the sixth transistor is the gate terminal of the sixth transistor.

13. A bias voltage generator, comprising:
a first bias voltage generating circuit, configured for generating a first bias voltage; and
a second bias voltage generating circuit, configured for generating a second bias voltage,
wherein the first bias voltage generating circuit comprises:
a first bias circuit, comprising a first transistor and a first current source; and
a first amplifier circuit, configured for generating the first bias voltage according to an input common mode voltage and a first feedback voltage from the first transistor,
wherein the first transistor comprises a first terminal coupled to a first supply voltage, a second terminal coupled to a first terminal of the first current source, and a third terminal coupled to the output terminal of the first amplifier circuit and configured for outputting the first bias voltage, and
wherein the second bias voltage generating circuit comprises:
a second bias circuit, comprising a second transistor and a second current source; and
a second amplifier circuit, configured for generating the second bias voltage according to the input common mode voltage and a second feedback voltage from the second transistor,
wherein the second transistor comprises a first terminal coupled to a ground voltage, a second terminal coupled to a first terminal of the second current source, and a third terminal coupled to the output terminal of the second amplifier circuit and configured for outputting the second bias voltage, and
wherein a second terminal of the first current source is coupled to the ground voltage and a second terminal of the second current source is coupled to the first supply voltage.

14. The bias voltage generator of claim 13, wherein the first amplifier circuit comprises:
a first input terminal, configured for receiving the input common mode voltage;
a second input terminal, coupled to a common node between the first transistor and the first current source and configured for receiving the first feedback voltage;
a supply voltage input terminal, coupled to a second supply voltage; and
an output terminal, coupled to the third terminal of the first transistor for generating the first bias voltage, and
wherein the second amplifier circuit comprises:
a first input terminal, configured for receiving the input common mode voltage;
a second input terminal, coupled to a common node between the second transistor and the second current source and configured for receiving the second feedback voltage;
a supply voltage input terminal, coupled to the second supply voltage; and
an output terminal, coupled to the third terminal of the second transistor for generating the second bias voltage.

15. The bias voltage generator of claim 13, wherein the first bias voltage and the second bias voltage are output from the third terminals of the first transistor and the second transistor respectively for biasing a buffer circuit, wherein a drain-source voltage of the first transistor in the first bias circuit is the same as a drain-source voltage of a first transistor in the buffer circuit and a drain-source voltage of the second transistor in the second bias circuit is the same as a drain-source voltage of a second transistor in the buffer circuit.

16. A bias voltage generator, comprising:
a first bias voltage generating circuit, configured for generating a first bias voltage; and
a second bias voltage generating circuit, configured for generating a second bias voltage,
wherein the first bias voltage generating circuit comprises:
a first bias circuit, comprising a first transistor and a first current source;
a first amplifier circuit, configured for generating the first bias voltage according to an input common mode voltage and a first feedback voltage from the first transistor; and
a first output isolation circuit, comprising a first circuit and a second circuit,
wherein the first transistor comprises a first terminal coupled to a first supply voltage, a second terminal coupled to a first terminal of the first current source, and a third terminal coupled to the first output isolation circuit, and
wherein the second bias voltage generating circuit comprises:
a second bias circuit, comprising a second transistor and a second current source;
a second amplifier circuit, configured for generating the second bias voltage according to the input common mode voltage and a second feedback voltage from the second transistor; and
a second output isolation circuit, comprising a third circuit and a fourth circuit,
wherein the second transistor comprises a first terminal coupled to a ground voltage, a second terminal coupled to a first terminal of the second current source, and a third terminal coupled to the second output isolation circuit,
wherein a second terminal of the first current source is coupled to the ground voltage and a second terminal of the second current source is coupled to the first supply voltage, and
wherein the second circuit is a replica of the first circuit and the fourth circuit is a replica of the third circuit, or
wherein the number of transistors in the second circuit is a multiple of the number of transistors in the first circuit, the number of transistors in the fourth circuit is a multiple of the number of transistors in the third circuit.

17. The bias voltage generator of claim 16, wherein the first amplifier circuit comprises:
a first input terminal, configured for receiving the input common mode voltage;
a second input terminal, coupled to a common node between the first transistor and the first current source and configured for receiving the first feedback voltage;
a supply voltage input terminal, coupled to a second supply voltage; and
an output terminal, coupled to the third terminal of the first transistor for generating the first bias voltage, and
wherein the second amplifier circuit comprises:
a first input terminal, configured for receiving the input common mode voltage;
a second input terminal, coupled to a common node between the second transistor and the second current source and configured for receiving the second feedback voltage;
a supply voltage input terminal, coupled to the second supply voltage; and
an output terminal, coupled to the third terminal of the second transistor for generating the second bias voltage.

18. The bias voltage generator of claim 16, wherein the first circuit comprises:
a third transistor and a third current source,
wherein the third transistor comprises a first terminal coupled to the ground voltage, a second terminal coupled to a first terminal of the third current source and a third terminal coupled to an output terminal of the first amplifier circuit, a second terminal of the third current source is coupled to the first supply voltage, and a common node between the third transistor and the third current source is coupled to the third terminal of the first transistor, and
wherein the second circuit comprises:
a fourth transistor and a fourth current source,
wherein the fourth transistor comprises a first terminal coupled to the ground voltage, a second terminal coupled to a first terminal of the fourth current source and a third terminal coupled to the output terminal of the first amplifier circuit, a second terminal of the fourth current source is coupled to the first supply voltage, and a common node between the fourth transistor and the fourth current source is configured for outputting the first bias voltage.

19. The bias voltage generator of claim 18, wherein the third circuit comprises:
a fifth transistor and a fifth current source,
wherein the fifth transistor comprises a first terminal coupled to the first supply voltage, a second terminal coupled to a first terminal of the fifth current source and a third terminal coupled to an output terminal of the second amplifier circuit, a second terminal of the fifth current source is coupled to the ground voltage, and a common node between the fifth transistor and the fifth current source is coupled to the third terminal of the second transistor, and
wherein the fourth circuit comprises:
a sixth transistor and a sixth current source,
wherein the sixth transistor comprises a first terminal coupled to the first supply voltage, a second terminal coupled to a first terminal of the sixth current source and a third terminal coupled to the output terminal of the second amplifier circuit, a second terminal of the sixth current source is coupled to the ground voltage, and a common node between the sixth transistor and the sixth current source is configured to outputting the second bias voltage.

20. The bias voltage generator of claim 19, wherein the first bias voltage and the second bias voltage are output from the bias voltage generator for biasing a buffer circuit, wherein a drain-source voltage of the first transistor in the first bias circuit is the same as a drain-source voltage of a first transistor in the buffer circuit and a drain-source voltage of the second transistor in the second bias circuit is the same as a drain-source voltage of a second transistor in the buffer circuit.
